(19) United States
(12) Patent Application Publication
(10) Pub. No.: US 2026/0165140 A1
(43) Pub. Date: Jun. 11, 2026

(54) METHOD AND APPARATUS FOR REDUCING WARPAGE IN SEMICONDUCTOR ELEMENT, AND METHOD FOR FORMING SEMICONDUCTOR PACKAGE

(71) Applicant: JCET STATS ChipPAC Korea Limited, Incheon (KR)

(72) Inventors: MinSung LEE, Incheon (KR); YeoJun YUN, Incheon (KR); HeeSoo LEE, Incheon (KR)

(21) Appl. No.: 19/405,441

(22) Filed: Dec. 2, 2025

(30) Foreign Application Priority Data
Dec. 6, 2024 (CN) 202411782703.4

(51) Int. Cl. H10W 42/00; H10P 58/00; H10P 72/78; H10W 72/00

(52) U.S. Cl. CPC H10W 42/121; H10P 58/00; H10P 72/78; H10W 72/07141; H10W 72/07232

(57) ABSTRACT

A method and an apparatus for reducing a warpage in a semiconductor element, and a method for forming a semiconductor package are provided. The method for reducing a warpage in a semiconductor element may include: providing a semiconductor element; disposing the semiconductor element on a carrier; applying a vacuum pressure on the semiconductor element to force the semiconductor element against the carrier to temporarily eliminate or reduce a warpage in the semiconductor element; and heating the semiconductor element with a laser beam to eliminate or reduce the warpage in the semiconductor element.

### TECHNICAL FIELD

The present application generally relates to semiconductor technology, and more particularly, to a method and an apparatus for reducing a warpage in a semiconductor element, and a method for forming a semiconductor package.

### BACKGROUND OF THE INVENTION

The semiconductor industry is constantly faced with complex integration challenges as consumers want their electronics to be smaller, faster and higher performance with more and more functionalities packed into a single device. High bandwidth memory (HBM) has recently attracted attention for offering significant performance gain in the form of a vertical stack of memory chips. However, with advancements in HBM requiring memory chips to become thinner to accommodate additional chip layers, issues such as chip warpage due to pressure and thickness limitations in densely stacked products needs to be addressed.

Therefore, a need exists for a semiconductor chip with reduced warpage.

### SUMMARY OF THE INVENTION

An objective of the present application is to provide a method for reducing a warpage in a semiconductor element.

According to an aspect of the present application, a method for reducing a warpage in a semiconductor element is provided. The method may include: providing a semiconductor element; disposing the semiconductor element on a carrier; applying a vacuum pressure on the semiconductor element to force the semiconductor element against the carrier to temporarily eliminate or reduce a warpage in the semiconductor element; and heating the semiconductor element with a laser beam to eliminate or reduce the warpage in the semiconductor element.

According to another aspect of the present application, an apparatus for reducing warpage in a semiconductor element is provided. The apparatus may include: a carrier having a plurality of vacuum holes and configured for supporting a semiconductor element; a vacuum apparatus coupled with the plurality of vacuum holes and configured for applying a vacuum pressure on the semiconductor element through the plurality of vacuum holes to force the semiconductor element against the carrier to temporarily eliminate or reduce a warpage in the semiconductor element; and a laser source configured to irradiate a laser beam to heat the semiconductor element to eliminate or reduce the warpage in the semiconductor element.

According to another aspect of the present application, a method for forming a semiconductor package is provided. The method may include: providing a plurality of semiconductor chips, wherein each of the plurality of semiconductor chips has a plurality of through-silicon vias (TSVs) formed therein, and at least one of the plurality of semiconductor chips has a warpage; disposing the at least one semiconductor chip on a carrier; applying a vacuum pressure on the at least one semiconductor chip to force the at least one semiconductor chip against the carrier to temporarily eliminate or reduce the warpage in the at least one semiconductor chip; and heating the at least one semiconductor chip with a laser beam to eliminate or reduce the warpage in the at least one semiconductor chip; and stacking the plurality of semiconductor chips on a top surface of a substrate to electrically connect every two adjacent semiconductor chips to each other via the TSVs thereof.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A is a cross-sectional view of a plurality of semiconductor chips stacked on a substrate, and FIG. 1B and FIG. 1C illustrate enlarged views of a first portion and a second portion of the semiconductor package shown in FIG. 1A.

FIGS. 2A to 2D are cross-sectional views illustrating various steps of a method for reducing a warpage in a semiconductor chip according to an embodiment of the present application.

FIGS. 3A to 3D are cross-sectional views illustrating various steps of a method for reducing a warpage in a semiconductor chip according to another embodiment of the present application.

FIGS. 4A to 4D are cross-sectional views illustrating various steps of a method for reducing a warpage in a semiconductor chip according to another embodiment of the present application.

FIGS. 5A to 5B are cross-sectional views illustrating various steps of a method for reducing a warpage in a high bandwidth memory (HBM) package according to an embodiment of the present application.

FIGS. 6A to 6H are cross-sectional views illustrating various steps of a method for forming a semiconductor package according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

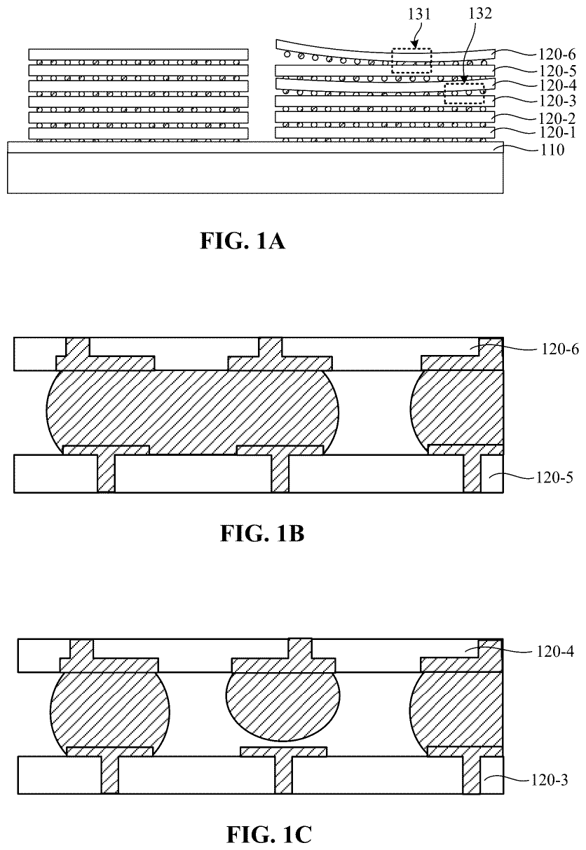

FIG. 1A is a cross-sectional view of a plurality of semiconductor chips 120-1 to 120-6 stacked on a substrate 110. For example, the plurality of semiconductor chips 120-1 to 120-6 may be memory chips, and may be interconnected by through-silicon vias (TSVs) and micro-bumps to form a high bandwidth memory (HBM). In order to reduce a thickness of the HBM, the micro-bumps become smaller (for example, about 20 μm) and the semiconductor chips 120-1 to 120-6 become thinner (for example, about 20 to 30 μm). Differences in coefficients of thermal expansion (CTEs) between different materials (for example, an epoxy molding compound and a semiconductor substrate) may lead to stress and deformation in one or more of the semiconductor chips 120-1 to 120-6, causing warping of the one or more semiconductor chips. FIG. 1B and FIG. 1C illustrate enlarged views of a first portion 131 and a second portion 132 of the semiconductor package shown in FIG. 1A, respectively. In an example, as shown in FIG. 1B, a shorted solder joint may be formed between the semiconductor chip 120-5 and the semiconductor chip 120-6 because of warpages of the semiconductor chip 120-5 and/or the semiconductor chip 120-6. In another example, as shown in FIG. 1C, an opened solder joint may be formed between the semiconductor chip 120-3 and the semiconductor chip 120-4 because of warpages of the semiconductor chip 120-3 and/or the semiconductor chip 120-4.

To address at least one of the above problems, a method for reducing a warpage in a semiconductor element is provided. The semiconductor element may include a wafer, a die, a package or any other elements formed using semiconductor manufacturing processes. In the method, the semiconductor element is disposed on a carrier, and a vacuum pressure is applied on the semiconductor element to force the semiconductor element against the carrier to temporarily eliminate or reduce a warpage in the semiconductor element. Then, the semiconductor element is heated with a laser beam to release internal stress in the semiconductor element, thereby eliminating or reducing the warpage in the semiconductor element.

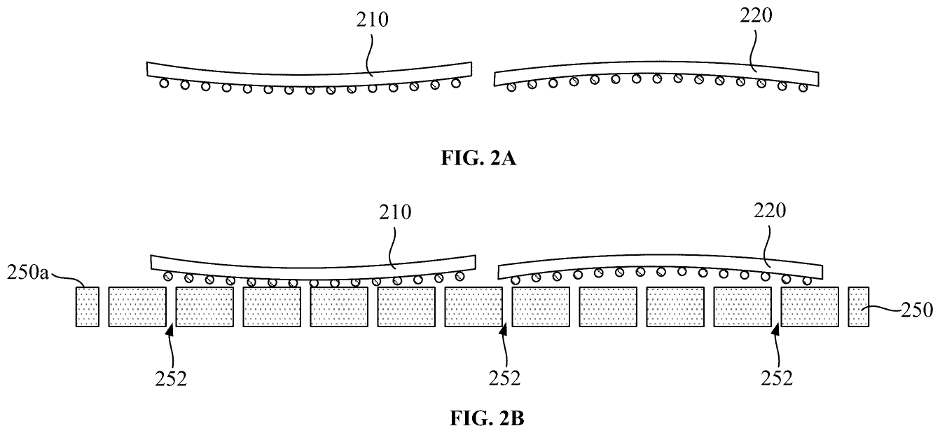

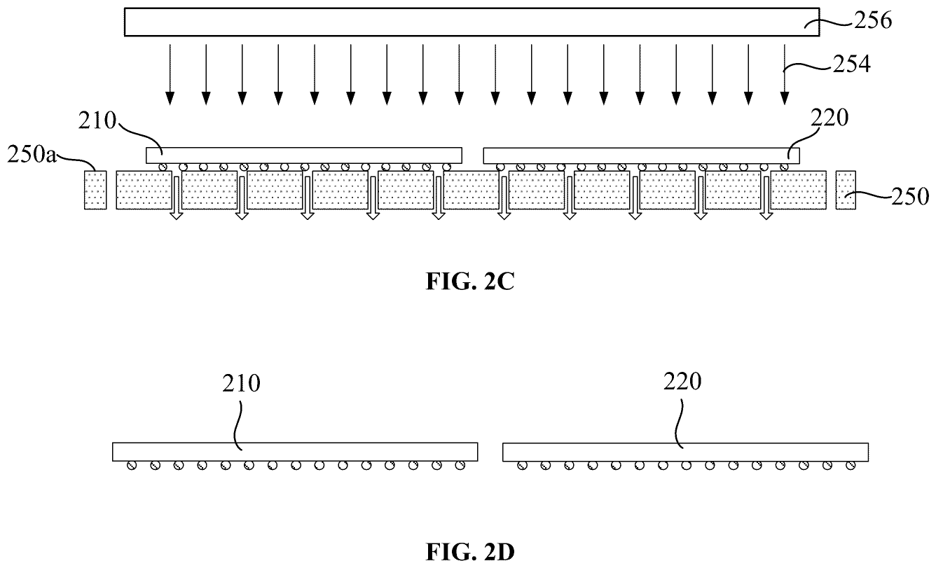

Referring to FIGS. 2A to 2D, various steps of a method for reducing a warpage in a semiconductor chip are illustrated according to an embodiment of the present application. In the following, the method will be described with references to FIGS. 2A to 2D in more details.

Referring to FIG. 2A, a semiconductor chip 210 having a concave warpage and a semiconductor chip 220 having a convex warpage are provided.

The semiconductor chips 210 and 220 be a memory chip such as a volatile memory (such as DRAM) or a non-volatile memory (such as ROM), a logic chip such as a field programmable gate array (FPGA) or an application-specific IC (ASIC), or any other types of semiconductor chips.

The semiconductor chips 210 and 220 may be formed using semiconductor manufacturing processes and include various materials. For example, the semiconductor chips 210 and 220 may include a semiconductor substrate (for example, silicon), an epoxy molding compound (EMC) layer, a redistribution layer (RDL) having conductive materials such as copper, conductive bumps (as shown in FIG. 2A), etc. These materials may have different coefficients of thermal expansion (CTE). During a cooling process, a material with a higher CTE will contract more than a material with a lower CTE, and this contraction difference may cause the materials to pull against each other and lead to internal stresses. As these materials are bonded together, the internal stresses may lead to bending or warping of the entire semiconductor chip. In some examples, the thicknesses of the semiconductor chips 210 and 220 may be small (for example, about 20 to 30 μm), and the mechanical strength of the semiconductor chips 210 and 220 will be small. The internal stress will cause the semiconductor chips 210 and 220 to warp significantly, which is not conducive to the further implementation of subsequent processes.

It could be understood that the present application is not limited to the above examples, the semiconductor chips 210 and 220 may include other materials and have different thicknesses. The semiconductor chips 210 and 220 may include a first layer having a first CTE and a second layer having a second CTE different from the first CTE, and the concave warpage of the semiconductor chip 210 and the convex warpage of the semiconductor chip 220 are at least partially caused by the difference between the first CTE and the second CTE.

Referring to FIG. 2B, the semiconductor chips 210 and 220 may be disposed on a carrier 250.

In some embodiments, the carrier 250 may have a flat top surface 250a, and the semiconductor chips 210 and 220 are disposed on the top surface 250a of the carrier 250. A plurality of vacuum holes 252 may be formed in the carrier 250, and a vacuum apparatus (not shown) may be coupled with the plurality of vacuum holes 252 to apply a vacuum pressure on the semiconductor chips 210 and 220 through the plurality of vacuum holes 252.

In some embodiments, the carrier 250 may be a heating block, which is also known as a dry bath incubator. The heating block may be controlled by a microprocessor, and can obtain a precise temperature stability. The heating block may have a supporting plate, and a plurality of vacuum holes may be formed in the supporting plate for applying a vacuum pressure.

However, the present application is not limited to the above embodiments, and the carrier 250 may have different configurations.

Referring to FIG. 2C, a vacuum pressure (as indicated by the hollow arrows) is applied on the semiconductor chips 210 and 220 to force the semiconductor chips 210 and 220 against the carrier 250 to temporarily eliminate or reduce the warpages in the semiconductor chips 210 and 220.

For example, the vacuum pressure may be generated by the vacuum apparatus coupled with the plurality of vacuum holes 252. The vacuum pressure is applied through the plurality of vacuum holes 252 to force the semiconductor chips 210 and 220 against the flat top surface 250a of the carrier 250. Thus, the semiconductor chips 210 and 220 may deform under the vacuum pressure, and the warpages in the semiconductor chips 210 and 220 can be temporarily eliminated or reduce.

Continuing referring to FIG. 2C, the semiconductor chips 210 and 220 are heated with laser beams 254 to eliminate or reduce the warpages in the semiconductor chips 210 and 220.

In some embodiments, as shown in FIG. 2C, a laser source 256 may be used to irradiate laser beams 254 on the semiconductor chips 210 and 220. The laser source 256 may be an excimer laser, a YAG laser, a YVO₄ laser, a YAlO₃ laser or a YLF laser of a pulse oscillation type or a continuous emission type. When using these lasers, it is efficient to converge the laser beams radiated from a laser oscillator into a linear or planar form by means of an optical system and then irradiate the converged beam onto the semiconductor chips 210 and 220. In some embodiments, the laser irradiation may be performed in the air, in the atmosphere of an inert gas such as nitrogen, or in a reduced pressure atmosphere. In some embodiments, a power of the laser source 256 may range from 4000 W to 6000 W (for example, 4500 W, 5000 W, 5500 W, etc.), and the irradiation using the laser beams 254 may be performed for a duration ranging from 1 second to 7 seconds (for example, 2 seconds, 3 seconds, 4 seconds, 5 seconds, 6 seconds, etc.) at a temperature ranging from 100° C. to 700° C. (for example, 150° C., 300° C., 450° C., 600° C., etc.). However, the heating treatment conditions may differ depending on the states of the semiconductor chips 210 and 220. Thus, an operator can determine the optimum heat treatment conditions as necessary.

During the irradiation, a momentary increase in temperature can be effected within the semiconductor chips 210 and 220, and the CTE difference between the first layer and the second may make a reversed shrink force, thereby releasing internal stress in the semiconductor chips 210 and 220. As the semiconductor chips 210 and 220 is forced against the flat top surface 250a of the carrier 250 by the vacuum pressure, the warpages in the semiconductor chips 210 and 220 can be eliminated or reduced. Then, after cooling down, the semiconductor chips 210 and 220 can be removed from the carrier 250, as shown in FIG. 2D.

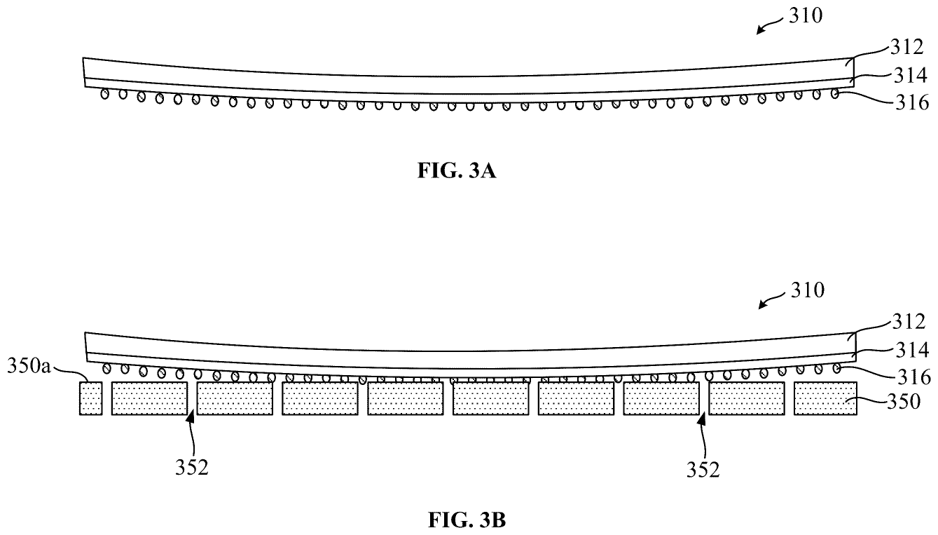

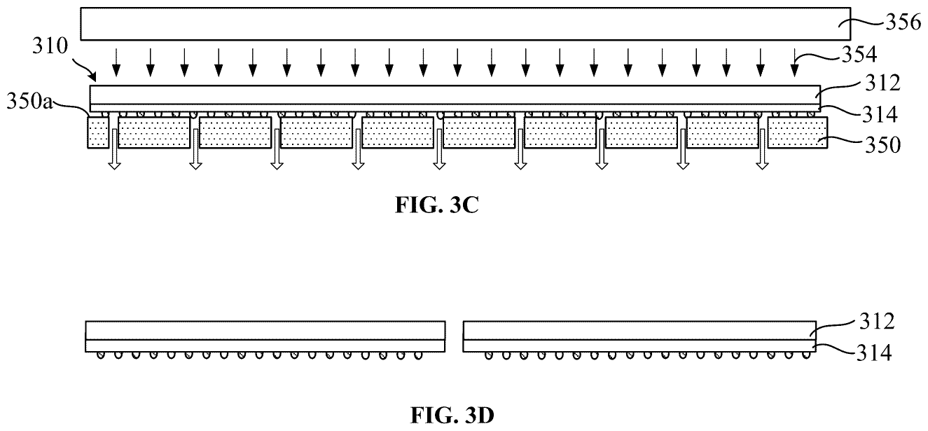

Referring to FIGS. 3A to 3D, various steps of a method for reducing a warpage in a semiconductor chip are illustrated according to another embodiment of the present application.

Referring to FIG. 3A, a semiconductor chip 310 is provided. The semiconductor chip 310 may include a semiconductor wafer 312 and a redistribution layer (RDL) 314 formed on the semiconductor wafer 312. In the example shown in FIG. 3A, a plurality of conductive bumps 316 are formed on the RDL 314. A plurality of semiconductor dice may be formed in the semiconductor chip 310 and separated by singulation channels. The singulation channels can provide cutting areas to singulate the semiconductor chip 310 into individual semiconductor dice in a singulation process.

In some embodiments, the semiconductor chip 310 may include silicon, germanium, gallium arsenide, gallium nitride, indium phosphide, silicon carbide or other material, and the RDL 314 may include a metallic material such as copper. The CTE of silicon chip is about 2.62 ppm/° C., while the CTE of copper is 2.62 ppm/° C. Thus, the CTE difference between the semiconductor wafer 312 and the RDL 314 may generate a warpage in the semiconductor chip 310. The semiconductor wafer 312 may have a large size (for example, having a diameter of 300 mm), and thus the warpage in the semiconductor chip 310 may be more severe.

Referring to FIG. 3B, the semiconductor chip 310 may be disposed on a top surface 350a of a carrier 350. A plurality of vacuum holes 352 may be formed in the carrier 350, and a vacuum apparatus (not shown) may be coupled with the plurality of vacuum holes 352 to apply a vacuum pressure on the semiconductor chip 310 through the plurality of vacuum holes 352.

Referring to FIG. 3C, a vacuum pressure (as indicated by the hollow arrows) is applied on the semiconductor chip 310 to force the semiconductor chip 310 against the carrier 350 to temporarily eliminate or reduce the warpage in the semiconductor chip 310. Then, the semiconductor chip 310 is heated with laser beams 354 irradiated from a laser source 356 to eliminate or reduce the warpage in the semiconductor chip 310.

During the irradiation with the laser beams 354, a momentary increase in temperature can be effected within the semiconductor chip 310, and the CTE difference between the semiconductor wafer 312 and the RDL 314 may make a reversed shrink force, thereby releasing internal stress in the semiconductor chip 310. As the semiconductor chip 310 is forced against the flat top surface 350a of the carrier 350 by the vacuum pressure, the warpage in the semiconductor chip 310 can be eliminated or reduced. Then, after cooling down, the semiconductor chip 310 is removed from the carrier 350 and is singulated into individual semiconductor dice, as shown in FIG. 3D.

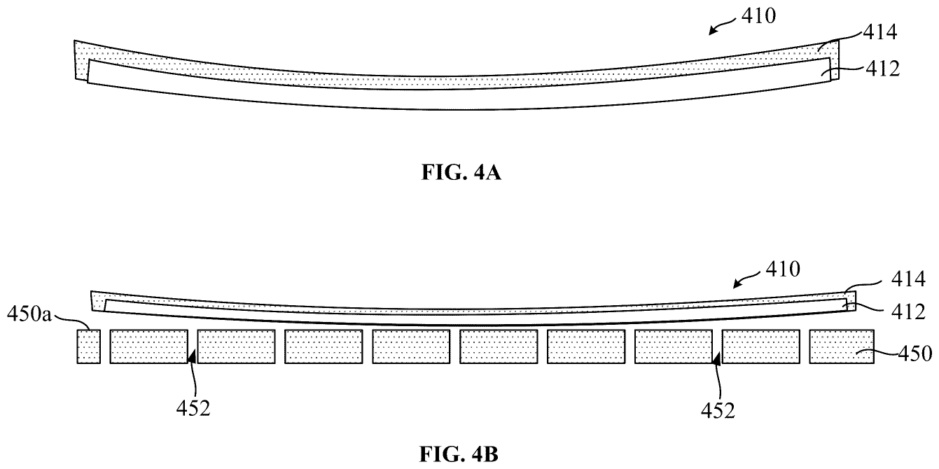

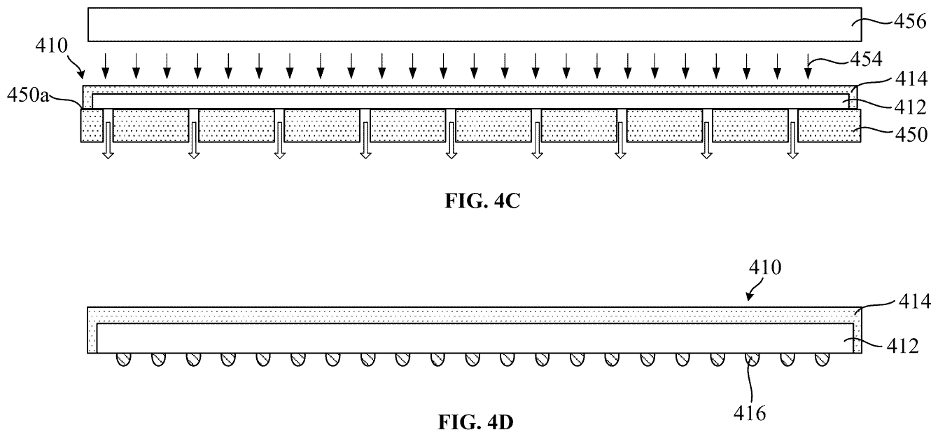

Referring to FIGS. 4A to 4D, various steps of a method for reducing a warpage in a semiconductor chip are illustrated according to another embodiment of the present application.

Referring to FIG. 4A, a semiconductor chip 410 is provided. The semiconductor chip 410 may include a first layer 412 including one or more electronic components, and a second layer 414 including an epoxy molding compound (EMC) layer encapsulating the one or more electronic components. The electronic components may include any of a variety of types of semiconductor dice, semiconductor packages, or discrete devices, and the EMC layer is used to mold the electronic components. The CTE difference between the electronic components and the EMC layer may generate a warpage in the semiconductor chip 410. In some embodiments, the semiconductor chip 410 may be formed using a fan-out wafer level packaging (FOWLP) technique.

Referring to FIG. 4B, the semiconductor chip 410 may be disposed on a top surface 450a of a carrier 450. A plurality of vacuum holes 452 may be formed in the carrier 450, and a vacuum apparatus (not shown) may be coupled with the plurality of vacuum holes 452 to apply a vacuum pressure on the semiconductor chip 410 through the plurality of vacuum holes 452.

Referring to FIG. 4C, a vacuum pressure (as indicated by the hollow arrows) is applied on the semiconductor chip 410 to force the semiconductor chip 410 against the carrier 450 to temporarily eliminate or reduce the warpage in the semiconductor chip 410. Then, the semiconductor chip 410 is heated with laser beams 454 irradiated from a laser source 456 to eliminate or reduce the warpage in the semiconductor chip 410.

During the irradiation with the laser beams 454, a momentary increase in temperature can be effected within the semiconductor chip 410, and the CTE difference between the electronic components and the EMC layer may make a reversed shrink force, thereby releasing internal stress in the semiconductor chip 410. As the semiconductor chip 410 is forced against the flat top surface 450a of the carrier 450 by the vacuum pressure, the warpage in the semiconductor chip 410 can be eliminated or reduced. Then, after cooling down, the semiconductor chip 410 is removed from the carrier 450.

Afterwards, as shown in FIG. 4D, a RDL (not shown) may be formed on a bottom surface of the semiconductor chip, and a plurality of conductive bumps 416 may be formed on the RDL. The conductive bumps 416 may be used for electrically connecting the semiconductor chip 410 to the external device or substrate.

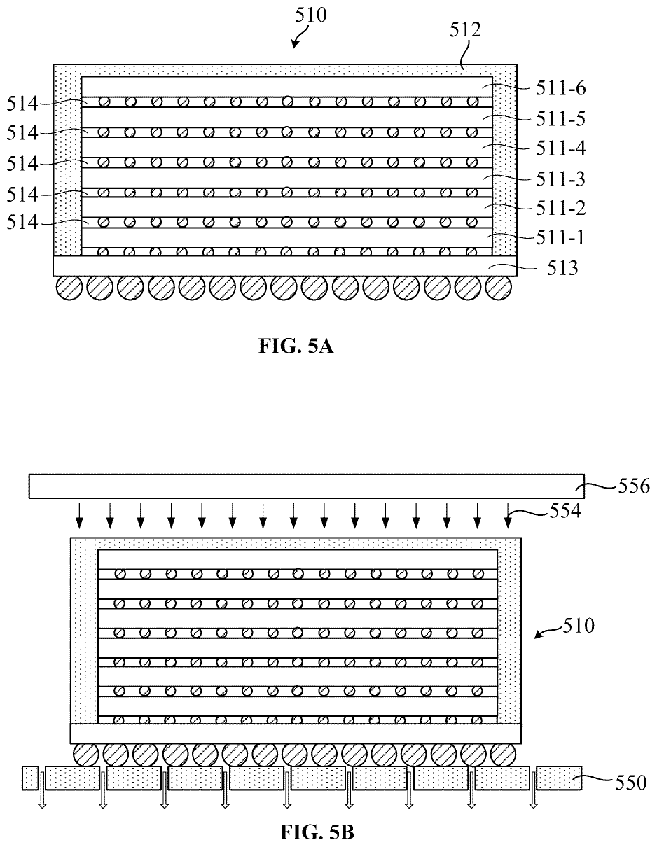

Referring to FIGS. 5A to 5B, various steps of a method for reducing a warpage in a high bandwidth memory (HBM) package are illustrated according to an embodiment of the present application.

Referring to FIG. 5A, a HBM package 510 is provided. The HBM package 510 may include a plurality of memory chips 511-1 to 511-6 stacked on a substrate 513. In some embodiments, the HBM package 510 may be fabricated using a thermal-compression non-conductive film (TC-NCF) technique. The HBM package 510 may include a non-conductive film (NCF) or a non-conductive paste (NCP) 514 disposed between every two adjacent memory chips, the NCF 514 may be heated and compressed to glue the two adjacent memory chips together. The HBM package 510 may further include an epoxy molding compound (EMC) layer 512 encapsulating the plurality of memory chips 511-1 to 511-6 and the NCFs 514. The CTE difference between the EMC layer 512 and the NCFs 514 may generate a warpage in the HBM package 510.

Referring to FIG. 5B, the HBM package 510 may be disposed on a carrier 550. A plurality of vacuum holes 552 may be formed in the carrier 550, and a vacuum apparatus (not shown) may be coupled with the plurality of vacuum holes 552 to apply a vacuum pressure on the HBM package 510 through the plurality of vacuum holes 552. The vacuum pressure (as indicated by the hollow arrows) is applied on the HBM package 510 to force the HBM package 510 against the carrier 550 to temporarily eliminate or reduce the warpage in the HBM package 510. Then, the HBM package 510 is heated with laser beams 554 irradiated from a laser source 556 to eliminate or reduce the warpage in the HBM package 510. During the irradiation with the laser beams 554, a momentary increase in temperature can be effected within the HBM package 510, and the CTE difference between the EMC layer 512 and the NCFs 514 may make a reversed shrink force, thereby releasing internal stress in the HBM package 510. As the HBM package 510 is forced against the flat top surface of the carrier 550 by the vacuum pressure, the warpage in the HBM package 510 can be eliminated or reduced. Then, after cooling down, the HBM package 510 is removed from the carrier 550.

According to another aspect of the present application, an apparatus for reducing warpage in a semiconductor chip is provided. The apparatus may include a carrier (for example, the carrier 250 shown in FIG. 2B, the carrier 350 shown in FIG. 3B, the carrier 450 shown in FIG. 4B, or the carrier 550 shown in FIG. 5B). The carrier may have a plurality of vacuum holes formed therein and configured for supporting a semiconductor chip having a warpage. The apparatus may further include a vacuum apparatus. The vacuum apparatus may be coupled with the plurality of vacuum holes and configured for applying a vacuum pressure on the semiconductor chip through the plurality of vacuum holes to force the semiconductor chip against the carrier to temporarily eliminate or reduce the warpage in the semiconductor chip. The apparatus may further include a laser source (for example, the carrier 256 shown in FIG. 2C, the carrier 356 shown in FIG. 3C, the carrier 456 shown in FIG. 4C, or the carrier 556 shown in FIG. 5B). The laser source may be configured to irradiate a laser beam to heat the semiconductor chip to eliminate or reduce the warpage in the semiconductor chip. More detail about the apparatus may refer to the above embodiments, and is not elaborated herein.

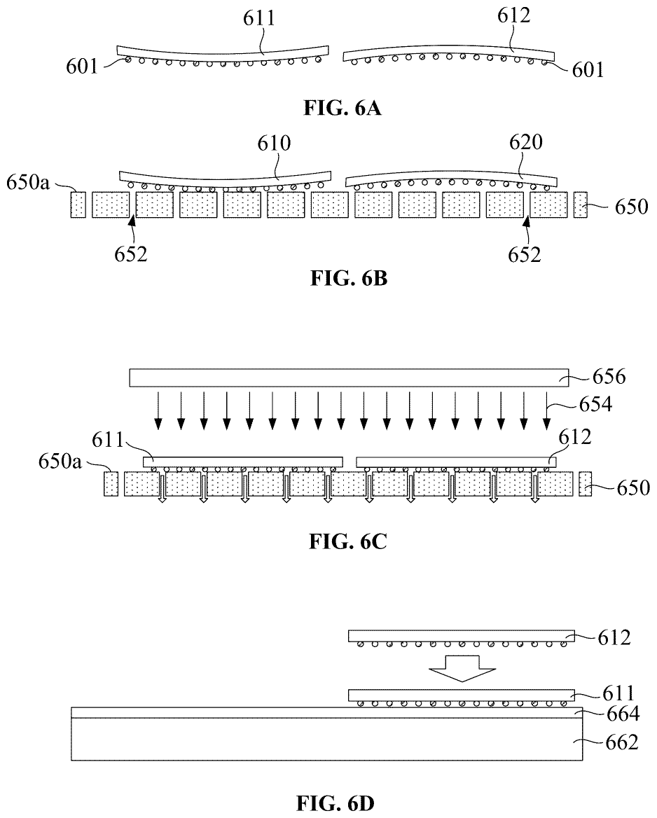

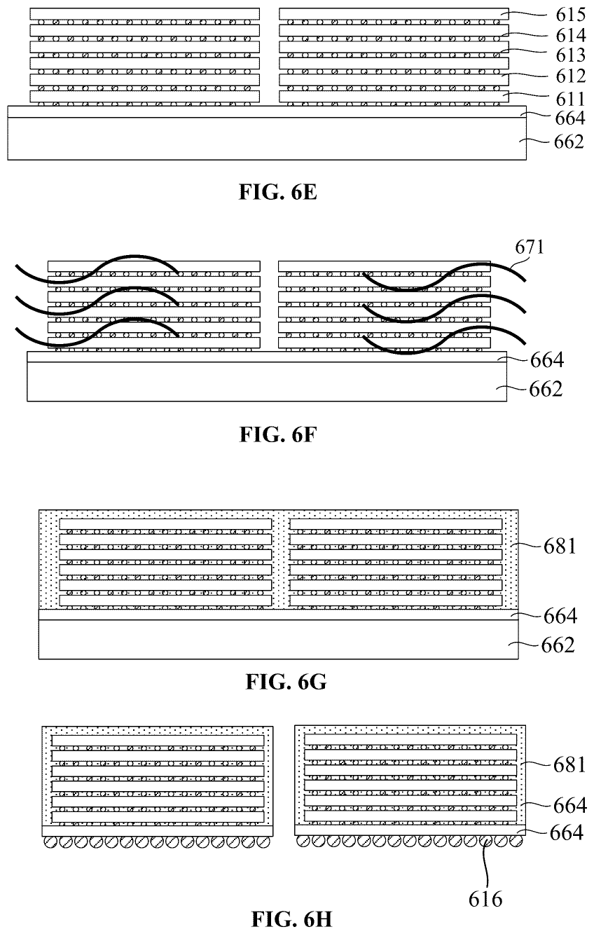

Referring to FIGS. 6A to 6H, various steps of a method for forming a semiconductor package are illustrated according to an embodiment of the present application. In the following, the method will be described with references to FIGS. 6A to 6H in more details.

Referring to FIG. 6A, a first semiconductor chip 611 and a second semiconductor chip 612 are provided. In an example, the first semiconductor chip 611 and the second semiconductor chip 612 may be a DRAM chip, and the semiconductor package to be formed is a HBM package. However, the present application is not limited thereto, the first semiconductor chip 611 and the second semiconductor chip 612 may be a logic chip such as a FPGA or an ASIC, or any other types of semiconductor chips.

The first semiconductor chip 611 and the second semiconductor chip 612 may be formed by semiconductor manufacturing processes and include various materials having different CTEs. Differences in CTEs between these materials may lead to stress and deformation in the first semiconductor chip 611 and the second semiconductor chip 612. For example, the first semiconductor chip 611 may have a concave warpage and the semiconductor chip 612 may have a convex warpage.

In some embodiments, each of the first semiconductor chip 611 and the second semiconductor chip 612 may have a plurality of through-silicon vias (TSVs) (not shown) and a plurality of connecting bumps 601 (for example, micro-bumps). At least some of the TSVs may be vertical vias extending completely from a top surface to a bottom surface of the first semiconductor chip 611 or the second semiconductor chip 612. The plurality of connecting bumps 601 are formed on the bottom surface of the first semiconductor chip 611 or the second semiconductor chip 612 and are electrically connected with the TSVs. In some examples, the connecting bumps 601 may be formed by depositing a solder material onto a metal post.

Referring to FIG. 6B, the first semiconductor chip 611 and the second semiconductor chip 612 may be disposed on a carrier 650. A plurality of vacuum holes 652 may be formed in the carrier 650, and a vacuum apparatus (not shown) may be coupled with the plurality of vacuum holes 652 to apply a vacuum pressure on the first semiconductor chip 611 and the second semiconductor chip 612 through the plurality of vacuum holes 652.

Referring to FIG. 6C, a vacuum pressure (as indicated by the hollow arrows) is applied on the first semiconductor chip 611 and the second semiconductor chip 612 to force the first semiconductor chip 611 and the second semiconductor chip 612 against the carrier 650 to temporarily eliminate or reduce the warpages in the first semiconductor chip 611 and the second semiconductor chip 612. For example, the vacuum pressure may be generated by the vacuum apparatus coupled with the plurality of vacuum holes 652. The vacuum pressure is applied through the plurality of vacuum holes 652 to force the first semiconductor chip 611 and the second semiconductor chip 612 against the flat top surface 650a of the carrier 650. Thus, the first semiconductor chip 611 and the second semiconductor chip 612 may deform under the vacuum pressure, and the warpages in the first semiconductor chip 611 and the second semiconductor chip 612 can be temporarily eliminated or reduce.

Then, the first semiconductor chip 611 and the second semiconductor chip 612 are heated with laser beams 654 irradiated from a laser source 656 to eliminate or reduce the warpages in the first semiconductor chip 611 and the second semiconductor chip 612. During the irradiation, a momentary increase in temperature can be effected within the first semiconductor chip 611 and the second semiconductor chip 612, and internal stresses in the first semiconductor chip 611 and the second semiconductor chip 612 can be released. As the first semiconductor chip 611 and the second semiconductor chip 612 is forced against the flat top surface 650a of the carrier 650 by the vacuum pressure, the warpages in the first semiconductor chip 611 and the second semiconductor chip 612 can be eliminated or reduced. Then, after cooling down, the first semiconductor chip 611 and the second semiconductor chip 612 can be removed from the carrier 650.

Afterwards, as shown in FIG. 6D, a substrate 664 is provided. The substrate 664 may be supported by a metal block 662, and then the first semiconductor chip 611 may be flip-chip stacked onto a top surface of the substrate 664. The substrate 664 can support the first semiconductor chip 611 and further connect the first semiconductor chip 611 with other electronic components which are also mounted on the substrate 664. By way of example, the substrate 664 may include a printed wiring board or a semiconductor substrate. However, the substrate 664 is not to be limited to these examples. In other examples, the substrate 664 may be a laminate interposer, a strip interposer, a leadframe, or other suitable substrates.

Then, the second semiconductor chip 612 may be stacked onto a top surface of the first semiconductor chip 611, enabling electrical contact between the connecting bumps 601 of the second semiconductor chip 612 and the TSVs of the first semiconductor chip 611.

Referring to FIG. 6E, more semiconductor chips such as a third semiconductor chip 613, a fourth semiconductor chip 614 and a fifth semiconductor chip 615 may be successively stacked on the second semiconductor chip 612. The semiconductor chip 613 to 615 may have the same or similar configurations and the first semiconductor chip 611 and the second semiconductor chip 612. In case of one or more of the semiconductor chips 613 to 615 have a warpage, the processes described with reference to FIG. 6A to FIG. 6D can be performed to reduce the warpage. In the example shown in FIG. 6E, to enhance manufacturing throughput, the substrate 664 may include a plurality of predefined substrate units arranged in a strip manner, thereby allowing some manufacturing processes to be performed on all the substrate units in parallel to form a plurality of HBM packages.

Referring to FIG. 6F, a mass reflow process is performed to reflow the connecting bumps 601 of all the semiconductor chips 611 to 615. For example, the heat 671 generated in the mass reflow process can melt the solder material of all connecting bumps 601 and form electrical connections between the connecting bumps 601 of and the TSVs.

Then, referring to FIG. 6G, an encapsulant 681 is formed on the top surface of the substrate 664 to encapsulate the plurality of semiconductor chips 611 to 615 and fill gaps among the plurality of semiconductor chips 611 to 615. In some embodiments, the encapsulant 681 may include liquid epoxy molding compound (EMC), and is formed by a molding process. The encapsulant 681 not only can protect the plurality of semiconductor chips 611 to 615 from external environment, but also can provide mechanical support to the plurality of semiconductor chips 611 to 615, helping to mitigate the risk of crack or delamination due to differential thermal expansions among the plurality of semiconductor chips 611 to 615.

Afterwards, referring to FIG. 6G and FIG. 6H, the substrate 664 is removed from the metal block 662, and a singulation step may be performed to singulate the substrate 664 to forms a plurality of individual semiconductor packages. In some embodiments, a plurality of conductive bumps 616 may be formed on the bottom surface of the semiconductor package. The conductive bumps 616 may be used for electrically connecting the semiconductor package to the external device or substrate.

It could be understood that the embodiment described above is only an example, and the present application is not limited thereto. For example, in some other embodiments, a thermal-compression non-conductive film (TC-NCF) technique may be used to form the semiconductor package. Taking the structure shown in FIG. 6D as an example, a non-conductive paste (NCP) or a non-conductive film (NCF) is formed on a top surface of the first semiconductor chip 611, the second semiconductor chip 612 is attached on the top surface of the first semiconductor chip 611 via the non-conductive paste or the non-conductive film; and then a thermal compression process is performed to electrically bond the connecting bumps of the second semiconductor chip 612 with the TSVs of the first semiconductor chip 611. Afterwards, other semiconductor chips can be successively bonded on the second semiconductor chip 612 to form the semiconductor package.

The discussion herein included numerous illustrative figures that showed various portions of a method and an apparatus for reducing a warpage in a semiconductor chip, and a method for forming a semiconductor package. For illustrative clarity, such figures did not show all aspects of each exemplary method or apparatus. Any of the example packages and/or methods provided herein may share any or all characteristics with any or all other packages and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for reducing a warpage in a semiconductor element, comprising:
providing a semiconductor element;
disposing the semiconductor element on a carrier;
applying a vacuum pressure on the semiconductor element to force the semiconductor element against the carrier to temporarily eliminate or reduce a warpage in the semiconductor element; and
heating the semiconductor element with a laser beam to eliminate or reduce the warpage in the semiconductor element.

2. The method of claim 1, wherein a plurality of vacuum holes are formed in the carrier, and the vacuum pressure is applied on the semiconductor element through the plurality of vacuum holes.

3. The method of claim 1, wherein the semiconductor element comprising a first layer having a first coefficient of thermal expansion (CTE) and a second layer having a second CTE different from the first CTE.

4. The method of claim 3, wherein the first layer comprises a semiconductor wafer, and the second layer comprises a redistribution layer (RDL) formed on the semiconductor wafer.

5. The method of claim 4, further comprising:
singulating the semiconductor wafer to form a plurality of dice.

6. The method of claim 3, wherein the first layer comprises one or more electronic components, and the second layer comprises an epoxy molding compound (EMC) layer encapsulating the one or more electronic components.

7. The method of claim 6, further comprising:
forming a redistribution layer (RDL) on a bottom surface of the semiconductor element; and
forming a plurality of conductive bumps on the RDL.

8. The method of claim 3, wherein the first layer comprises an epoxy molding compound (EMC) layer, and the second layer comprises a non-conductive film (NCF) or a non-conductive paste (NCP).

9. An apparatus for reducing warpage in a semiconductor element, comprising:
a carrier having a plurality of vacuum holes and configured for supporting a semiconductor element;
a vacuum apparatus coupled with the plurality of vacuum holes and configured for applying a vacuum pressure on the semiconductor element through the plurality of vacuum holes to force the semiconductor element against the carrier to temporarily eliminate or reduce a warpage in the semiconductor element; and
a laser source configured to irradiate a laser beam to heat the semiconductor element to eliminate or reduce the warpage in the semiconductor element.

10. A method for forming a semiconductor package, comprising:
providing a plurality of semiconductor chips, wherein each of the plurality of semiconductor chips has a plurality of through-silicon vias (TSVs) formed therein, and at least one of the plurality of semiconductor chips has a warpage;
disposing the at least one semiconductor chip on a carrier;
applying a vacuum pressure on the at least one semiconductor chip to force the at least one semiconductor chip against the carrier to temporarily eliminate or reduce the warpage in the at least one semiconductor chip; and
heating the at least one semiconductor chip with a laser beam to eliminate or reduce the warpage in the at least one semiconductor chip; and
stacking the plurality of semiconductor chips on a top surface of a substrate to electrically connect every two adjacent semiconductor chips to each other via the TSVs thereof.

11. The method of claim 10, wherein each of the plurality of semiconductor chips has a plurality of connecting bumps formed on its bottom surface.

12. The method of claim 11, further comprising:
performing a mass reflow process to reflow the connecting bumps; and
forming an encapsulant on the top surface of the substrate to encapsulate the plurality of semiconductor chips and fill gaps among the plurality of semiconductor chips.

13. The method of claim 11, wherein the plurality of semiconductor chips comprises a first semiconductor chip and a second semiconductor chip, and the method further comprises:
forming a non-conductive paste or a non-conductive film on a top surface of the first semiconductor chip;
attaching the second semiconductor chip on the top surface of the first semiconductor chip via the non-conductive paste or the non-conductive film; and
performing a thermal compression process to electrically bond the connecting bumps of the second semiconductor chip with the TSVs of the first semiconductor chip.

14. The method of claim 10, wherein the plurality of semiconductor chips comprises one or more memory chips.

15. The method of claim 11, further comprising:
forming a plurality of conductive bumps on a bottom surface of the substrate.
